(19) United States
(12) Patent Application Publication
(10) Pub. No.: US 2008/0074116 A1
(43) Pub. Date: Mar. 27, 2008

(54) Advanced air bearing and detection method for media glide testing at ultra-low flying height

(75) Inventors: Dougman Kim, Campbell, CA (US); Shuyu Zhang, Fremont, CA (US)

Correspondence Address: IRELL & MANELLA LLP, 840 NEWPORT CENTER DRIVE, SUITE 400, NEWPORT BEACH, CA, 92660, US

(73) Assignee: Samsung Electronics Co., Ltd., Suwon City (KR)

(21) Appl. No.: 11/528,028

(22) Filed: Sep. 26, 2006

(51) Int. Cl. G01R 31/02; G01R 31/327

(52) U.S. Cl. 324/421

(57) ABSTRACT

A glide head assembly that can be used to certify disks of hard disk drives. The assembly includes a glide head that is coupled to a suspension arm. The assembly further has a contact sensor coupled to the head. The contact sensor includes a center plate and four beams. The beams are coupled to corresponding sensor elements. Contact between the head and the disk will cause the beams to deflect. The deflection of the beams is sensed by the sensor elements and processed to detect head/disk contact. The number, orientation and amplitude of the beams that are deflected can be processed to determine the pitch and roll angles of the glide head.

### BACKGROUND OF THE INVENTION

1. Field of the Invention

The present invention relates to a glide test head used to certify a disk of a hard disk drive.

2. Background Information

Hard disk drives contain a plurality of magnetic heads that are coupled to rotating disks. The heads write and read information by magnetizing and sensing the magnetic fields of the disk surfaces. Each head is attached to a flexure arm to create a subassembly commonly referred to as a head gimbal assembly (“HGA”)). The HGA's are suspended from an actuator arm. The actuator arm has a voice coil motor that can move the heads across the surfaces of the disks.

In operation, each head is separated from a corresponding disk surface by an air bearing. The air bearing minimizes the mechanical wear between the head and the disk. The strength of the magnetic field is inversely proportional to the height of the air bearing. A smaller air bearing results in a stronger magnetic field on the disks, and vice versa.

The heads typically fly very close to the disk. Any protrusions or other surface irregularities in the disk surfaces may create contact between the heads and the disks. Such contact may cause mechanical wear between the components. Additionally, contact between the heads and disk surfaces may create particles or other by-products that may contaminant the drive.

When mass producing disk drives, the disks are tested to insure a desired surface finish and to determine the magnetic characteristics of each disk. Disks that do not meet certain standards are either re-worked or discarded. Disks are typically tested in a system commonly referred to as a disk certifier. Disk certifiers contain glide heads that can be used to test disks that are loaded onto a spindle motor of the certifier. The certifier also contains electronic circuits that can be used to perform tests. The glide head may be coupled to a contact sensor, such as a piezoelectric transducer, used to count the number of times the glide head makes contact with the disk surface.

It is desirable to vary the flying height of the glide head during testing to obtain data on the surface of the disk. The flying height can be varied by lowering the velocity of the disk. Lowering the disk velocity introduces a number of problems. First, the impact energy is proportional to the square of the velocity. At very low velocities it can be difficult to actually detect contact by the head. Second, the head becomes less stable at lower disk velocities. Finally, changing the velocity can affect the pitch and roll of the glide head. It is desirable to provide a glide head that has a stable fly at low linear velocities. It would also be desirable to provide a glide head that can detect contact at high linear velocities such as 300 inches per second or greater.

Conventional glide heads include a pair of rails separated by a central cavity. Each rail may have an associated electromechanical transducer. Generally, one of the two rails generates a stronger output signal when the glide head detects a defect such as an asperity. This degrades the accuracy of defect data in terms of location and amplitude. It would be desirable to have a glide head that detects contact at the trailing edge of a central pad.

The electromechanical transducer is typically a piezoelectric device. The sensitivity of the transducer can be improved by increasing the thickness of the piezoelectric material. Increasing the thickness of the piezoelectric also increases the stiffness of the glide head which affects the flying height characteristics of the head.

The flying height performance of a glide head can be obtained using a fly height detector. Fly height detectors typically contain a glass disk that rotates adjacent to the glide head. A light beam is directed through the glass and reflected from the glide head. The reflected light is detected and analyzed to determine the fly height of the glide head. Glide heads are typically constructed from aluminum oxide titanium carbide (AlTiC) material. AlTiC is a two phase material with discrete boundaries between particles. This material structure can create errors in analyzing the reflected light in a fly height tester.

### BRIEF SUMMARY OF THE INVENTION

A glide head assembly that is used to certify a disk of a hard disk drive. The glide head includes a suspension arm and a glide head. The assembly also includes a contact sensor that is connected to the head and the suspension arm. The contact sensor includes a center plate and a plurality of beams that are coupled to a substrate. The contact sensor also includes a plurality of sensor elements coupled to the beams.

### BRIEF DESCRIPTION OF THE DRAWINGS

FIG. 1 is a top view of an embodiment of a hard disk drive;

FIG. 2 is a top enlarged view of a head of the hard disk drive;

FIG. 3 is a schematic of a disk certifier for testing disks of hard disk drives;

FIG. 4 is an illustration of a glide head assembly;

FIG. 5 is a top view of a contact sensor of the glide head assembly;

FIG. 6 is an illustration of an air bearing surface of a glide head;

FIG. 7 is an alternate embodiment of the air bearing surface.

### DETAILED DESCRIPTION

Disclosed is a glide head assembly that can be used to certify disks of hard disk drives. The assembly includes a glide head that is coupled to a suspension arm. The assembly further has a contact sensor coupled to the head. The contact sensor includes a center plate and four beams. The beams are coupled to corresponding sensor elements. Contact between the head and the disk will cause the beams to deflect. The deflection of the beams is sensed by the sensor elements and processed to detect head/disk contact. The number, orientation and amplitude of the beams that are deflected can be processed to determine the pitch and roll angles of the disk.

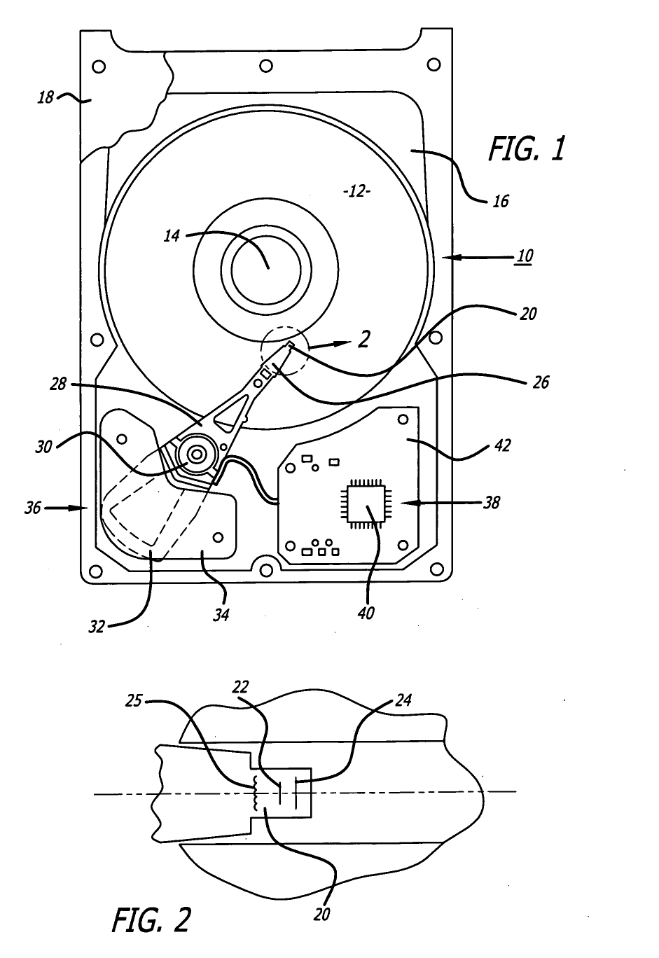

Referring to the drawings more particularly by reference numbers, FIG. 1 shows an embodiment of a hard disk drive 10. The disk drive 10 may include one or more magnetic disks 12 that are rotated by a spindle motor 14. The spindle motor 14 may be mounted to a base plate 16. The disk drive 10 may further have a cover 18 that encloses the disks 12.

The disk drive 10 may include a plurality of heads 20 located adjacent to the disks 12. As shown in FIG. 2 the heads 20 may have separate write 24 and read elements 22. The write element 24 magnetizes the disk 12 to write data. The read element 22 senses the magnetic fields of the disks 12 to read data. By way of example, the read element 22 may be constructed from a magneto-resistive material that has a resistance which varies linearly with changes in magnetic flux.

Referring to FIG. 1, each head 20 may be gimbal mounted to a flexure arm 26 as part of a head gimbal assembly (HGA). The flexure arms 26 are attached to an actuator arm 28 that is pivotally mounted to the base plate 16 by a bearing assembly 30. A voice coil 32 is attached to the actuator arm 28. The voice coil 32 is coupled to a magnet assembly 34 to create a voice coil motor (VCM) 36. Providing a current to the voice coil 32 will create a torque that swings the actuator arm 28 and moves the heads 20 across the disks 12.

The hard disk drive 10 may include a printed circuit board assembly 38 that includes a plurality of integrated circuits 40 coupled to a printed circuit board 42. The printed circuit board 40 is coupled to the voice coil 32, heads 20 and spindle motor 14 by wires (not shown).

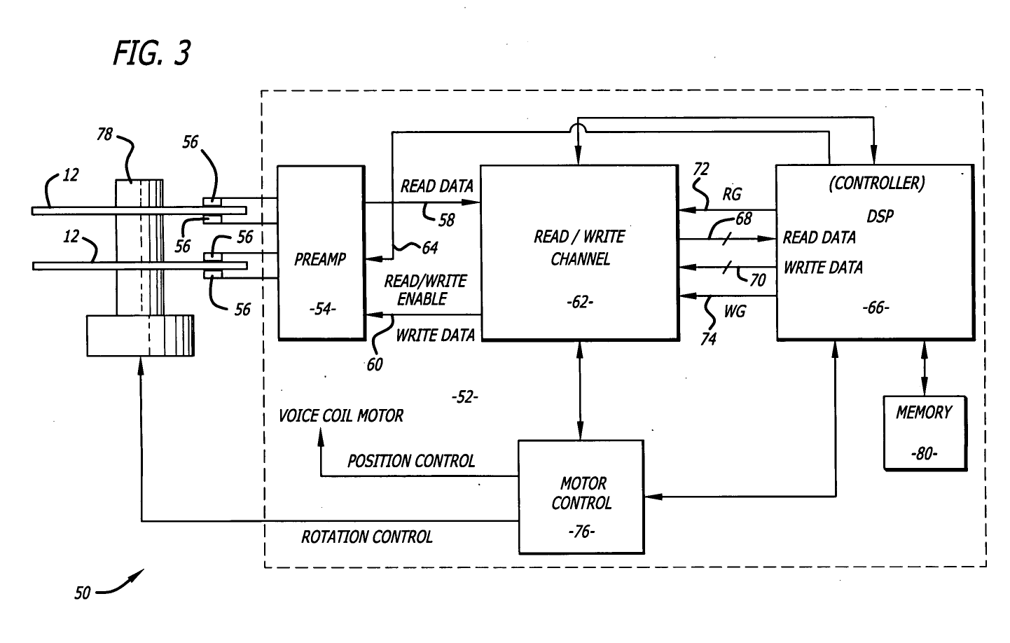

FIG. 3 shows an embodiment of a disk certifier 50 that can be used to test and certify whether one or more disks comply with certain factory specifications. The certifier 50 may include various electrical circuits 52 for reading and writing data onto the disks 12. The circuits may include a pre-amplifier circuit 54 that is coupled to a plurality of glide head assemblies 56. There may be a glide head assembly 56 for each disk surface. The pre-amplifier circuit 54 has a read data channel 58 and a write data channel 60 that are connected to a read/write channel circuit 62. The pre-amplifier 54 also has a read/write enable gate 64 connected to a controller 66. Data can be written onto the disks 12, or read from the disks 12 by enabling the read/write enable gate 64.

The read/write channel circuit 62 is connected to the controller 66 through read and write channels 68 and 70, respectively, and read and write gates 72 and 74, respectively. The read gate 72 is enabled when data is to be read from the disks 12. The write gate 74 is to be enabled when writing data to the disks 12. The controller 66 may be a digital signal processor that operates in accordance with a software routine, including a routine(s) to write and read data from the disks 12. The read/write channel circuit 62 and controller 66 may also be connected to a motor control circuit 76 which controls a voice coil motor (not shown) and a spindle motor 78 of the certifier 10. The voice coil motor can move the glide heads 56 relative to the disks 12. The controller 66 may be connected to a non-volatile memory device 80. By way of example, the device 80 may be a read only memory (“ROM”)) that contains instructions that are read by the controller 66. The disks 12 can be leaded and unloaded from the spindle motor 78 so that disks can be continuously tested by the certifier 50.

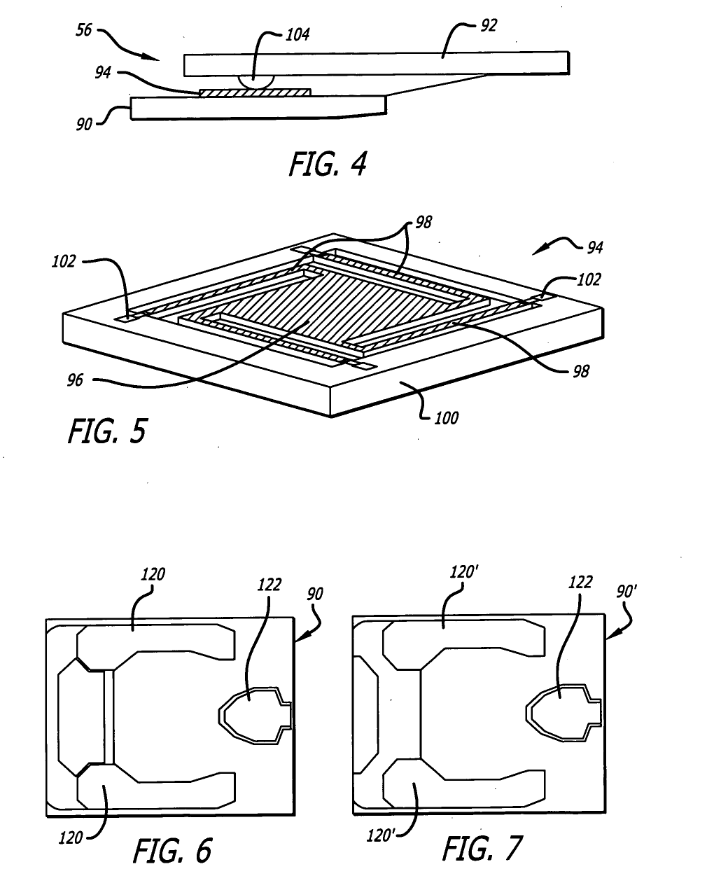

As shown in FIG. 4, the head glide assembly 56 may include a glide head 90 that is coupled to a suspension arm 92. The suspension arm 92 may be constructed from flexure materials known by those skilled in the art to support a head. The assembly 56 further includes a contact sensor 94 that is coupled to the head.

FIG. 5 shows an embodiment of a contact sensor 94. The sensor 94 includes a center plate 96 and a plurality of beams 98 supported by a substrate 100. Each beam 98 has a corresponding sensor element 102. By way of example, the sensor elements 102 may each be a piezoelectric transducer with wires (not shown) that are connected to the certifier. The center plate 96 may be attached to a pivot 104 of the suspension arm 102 (see FIG. 4). The substrate 100 may be attached to the glide head 90.

Contact between the glide head 90 and a disk will create impact energy that transfers to the contact sensor 94. The impact energy will cause one or more of the beams 98 to deflect. The number of beams that are deflected and the amplitude of each deflected beam can be analyzed to determine various characteristics of the impact. For example, the location of impact on the head may be determined and mapped to locate various defects on the disk. Additionally, pitch and roll angles of the disk may be determined from the data produced by the deflected beams.

FIGS. 6 and 7 shows two embodiments of a glide head 90 and 90′, respectively. The heads 90 and 91 may be constructed from a SiC or CaTiO₃ material. Such materials have favorable optical properties when the head is flown in an optical fly height tester. Each head may include air bearing surface pads 120 and 120′ and a central pad 122 or 122′, respectively. The air bearing surface pads 120 may create a negative pressure air bearing surface that increases the stability of the head 90. The air bearing surface pads 120 may have various steps to control the minimum flying height at the trailing edge of the head.

While certain exemplary embodiments have been described and shown in the accompanying drawings, it is to be understood that such embodiments are merely illustrative of and not restrictive on the broad invention, and that this invention not be limited to the specific constructions and arrangements shown and described, since various other modifications may occur to those ordinarily skilled in the art.

The air bearing surface can cause the glide head 90 to, make disk contact at relatively high velocities such as 300 inches per second. The air bearing surface may have an etched recession 124′. The recession 124′ can cause a high enough pivot angle that together with the positive pitch static angle and zero crown creates enough dynamic pitch to induce contact at the trailing edge of the central pad 122.

What is claimed is:

1. A glide head assembly used to test a disk of a hard disk drive, comprising:
a suspension arm;
a glide head coupled to said suspension arm; and,
a contact sensor connected to said head, said contact sensor including a center plate and a plurality of beams coupled to a substrate, said contact sensor further including a plurality of sensor elements coupled to said beams.

2. The glide head assembly of claim 1, wherein said beams are separated from each other.

3. The glide head assembly of claim 2, wherein said contact sensor includes four beams that arranged in a rectangular pattern.

4. The glide head assembly of claim 1, wherein said sensor elements include piezoelectric transducers.

5. The glide head assembly of claim 1, wherein said contact sensor is attached to said glide head and a pivot of said suspension arm.

6. The glide head assembly of claim 5, wherein said center plate is attached to said pivot and said substrate is attached to said glide head.

7. A glide head assembly used to test a disk of a hard disk drive, comprising:
a suspension arm;
a glide head coupled to said suspension arm; and,
contact sensor means for sensing a contact between said glide head and the disk.

8. The glide head assembly of claim 7, wherein said contact sensor means senses a pitch and roll of the disk.

9. The glide head assembly of claim 7, wherein said contact sensor means includes a center plate and a plurality of beams coupled to a substrate, said contact sensor further including a plurality of sensor elements coupled to said beams.

10. The glide head assembly of claim 9, wherein said beams are separated from each other.

11. The glide head assembly of claim 10, wherein said contact sensor includes four beams that arranged in a rectangular pattern.

12. The glide head assembly of claim 9, wherein said sensor elements include piezoelectric transducers.

13. The glide head assembly of claim 9, wherein said contact sensor is attached to said glide head and a pivot of said suspension arm.

14. The glide head assembly of claim 13, wherein said center plate is attached to said pivot and said substrate is attached to said glide head.

15. A method for certifying a disk of a hard disk drive, comprising:
coupling a disk to a spindle motor;
rotating the disk;
flying a glide head adjacent to the disk wherein the glide head makes contact with the disk; and, sensing the contact with a plurality of beams of a contact sensor.

16. The method of claim 15, wherein the contact is sensed by a plurality of sensor elements that sense beam deflections of the beams.

17. The method of claim 15, further comprising sensing a pitch and roll of the disk.

18. The method of claim 15, further comprising attaching a center plate of the contact sensor to a suspension arm, and a substrate of the contact sensor to the glide head.
